(19) United States
(12) Patent Application Publication
(10) Pub. No.: US 2015/0008478 A1
(43) Pub. Date: Jan. 8, 2015

(54) SEMICONDUCTOR DEVICE AND MANUFACTURING METHOD OF THE SAME

(71) Applicant: DENSO CORPORATION, Kariya-city, Aichi-pref (JP)

(72) Inventors: Weitao Cheng, Nukata-gun (JP); Shinji Amano, Okazaki-city (JP); Yoshifumi Okabe, Anjo-city (JP); Tomofusa Shiga, Nukata-gun (JP)

(21) Appl. No.: 14/371,543

(22) PCT Filed: Jan. 22, 2013
(86) PCT No.: PCT/JP2013/000283

§ 371 Date: Jul. 10, 2014

(30) Foreign Application Priority Data
Jan. 23, 2012 (JP) 2012-011127
Dec. 24, 2012 (JP) 2012-280404

(51) Int. Cl. H01L 29/66; H01L 29/78; H01L 21/322; H01L 29/739

(52) U.S. Cl. CPC H01L 29/66333; H01L 29/7395; H01L 29/7813; H01L 29/66734; H01L 21/3221
USPC 257/139; 438/138; 438/473; 257/330

(57) ABSTRACT

A manufacturing method of a semiconductor device includes applying at least one of a particle ray and a radial ray to a surface of a semiconductor substrate on which a transistor including a gate insulation film and a gate electrode has been formed adjacent to the surface, and annealing the semiconductor substrate for recovering a crystal defect contained in the gate insulation film and the gate electrode, after the applying. Further, the manufacturing method includes pre-annealing for reducing a content of a hydrogen molecule and a water molecule contained in the gate insulation film and the gate electrode to a predetermined concentration, before the applying. In the semiconductor device manufactured by this method, a concentration of thermally stable defect existing in the gate insulation film is reduced to a predetermined concentration.

### CROSS REFERENCE TO RELATED APPLICATIONS

The present disclosure is based on Japanese Patent Applications No. 2012-11127 filed on Jan. 23, 2012 and No. 2012-280404 filed on Dec. 24, 2012, the disclosures of which are incorporated herein by reference.

### TECHNICAL FIELD

The present disclosure relates to a manufacturing method of a semiconductor device, which includes a step of applying at least one of a radial ray and a particle ray for lifetime control, and a semiconductor device manufactured by the method.

### BACKGROUND ART

In recent years, switching devices with low power consumption have been employed in industrial equipment or household electrical appliances for saving energy. As such a switching device, a MOS-type field effective transistor (MOSFET) is known.

Since the MOSFET is used at a high frequency, switching speed is adjusted by performing the lifetime control. Examples of the method of the lifetime control are diffusion of a heavy metal such as platinum, applying of a particle ray such as an electron ray, and applying of a radial ray such as a gamma ray. When the method of applying the particle ray or the method of applying the radial ray is employed, a crystal defect occurs in a semiconductor substrate as a target, resulting in the trap of electrons and holes. Therefore, extinction of minority carriers is enhanced, and the lifetime can be shortened, as compared with a case without applying the particle ray. As such, the lifetime can be controlled by adjusting the type of the particle ray, energy of applying the particle ray, and intensity of applying the particle ray.

However, when the particle ray or the radial ray is applied, a hole trap level at an interface between a gate insulation film and the semiconductor substrate is increased, and hence a threshold voltage is lowered. After the particle ray or the radial ray is applied, for the purpose of the lifetime control, an annealing process is performed at a temperature that does not recover the defect formed in the semiconductor substrate, for example, at a temperature from 300 to 400 degrees Celsius (° C.). By this process, an unstable trap level in the gate insulation film disappears, and hence the threshold voltage increases.

However, because the trap, which are generated in the step of applying, cannot be fully disappeared at this annealing temperature, it is difficult to raise the threshold voltage to the level before the step of applying. This is because hydrogen ion or radical is generated due to hydrogen or water molecule contained in an element being decomposed by the particle ray or the radial ray, and generates a large amount of hole trap, which is relatively stable among crystal defects, as interacting with Si—Si bond in a gate oxide film cut by the step of applying.

Patent documents 1 and 2 describe a method of increasing the threshold voltage before the particle ray or the radial ray is applied to be higher than a desired voltage by setting the concentration of impurity doped to a semiconductor substrate (particularly, a channel region) to a high level beforehand. That is, the shortage of increase in the threshold voltage due to the annealing after the applying, relative to the decreased amount of the threshold voltage caused by the applying, is compensated by setting the impurity concentration of the channel region to the high level.

### PRIOR ART DOCUMENTS

### Patent Documents

Patent Document 1: JP 2002-184986 A (corresponding to United States Patent Application Publication No. 2002/0109183 A1) Patent Document 2: JP 2000-200792 A

### SUMMARY OF INVENTION

In the methods of the patent documents 1, 2, there is a possibility that variation in threshold voltage is likely to increase due to the increase in concentration of the channel region. Further, there is a possibility that switching loss increases.

The present disclosure is made in view of the foregoing issues, and it is an object of the present disclosure, in a method of manufacturing a semiconductor device in which at least one of a particle ray and a radial ray is applied for lifetime control, to ensure a threshold voltage at a level before the at least one of the particle ray and the radial ray is applied without increasing an impurity concentration of a semiconductor substrate. Also, it is an object of the present disclosure to provide a semiconductor device that ensures the threshold voltage at a level that is before the applying of the at least one of the particle ray and the radial ray.

According to a first aspect of the present disclosure, a manufacturing method of a semiconductor device includes: an element forming step of forming an element including a transistor on a semiconductor substrate, the transistor having a gate insulation film and a gate electrode adjacent to a surface of the semiconductor substrate; an applying step of applying one of a particle ray and a radial ray toward the surface of the semiconductor substrate, after the element forming step; and an annealing step of heating the semiconductor substrate for recovering a crystal defect contained in the gate insulation film and the gate electrode, after the applying step. The above-described method further includes a pre-annealing step of heating the semiconductor substrate for reducing a content of hydrogen molecules and water molecules contained in the gate insulation film and the gate electrode, before the applying step.

By employing this manufacturing method of the semiconductor device, the number of the hydrogen molecules or the water molecules contained in the gate insulation film and the gate electrode can be reduced before the applying step in which the particle ray or the radial ray is applied for the purpose of lifetime control. Therefore, among the defects generated by the applying step, a component of hole trap stable to the annealing step performed after the applying step can be reduced. That is, the stable hole trap generated in the gate insulation film by the applying step can be greatly reduced. As such, the defect contained in the gate insulation film can be almost recovered only by the annealing step, and thus a threshold voltage can be recovered to a level before the applying step. In other words, the threshold voltage can be recovered by the annealing step performed after the applying, without requiring to set an impurity concentration of the semiconductor substrate, which determines the threshold voltage, to a higher level beforehand.

According to a second aspect of the present disclosure, the content of the hydrogen molecules and the water molecules contained in the gate insulation film and the gate electrode is made less than 6×10²¹ cm⁻³ by the pre-annealing step.

The inventors confirmed a characteristic that a shift amount of a threshold voltage depends on the content of the hydrogen molecules and water molecules through a computer simulation (see FIG. 8 of “Embodiments for Carrying out Invention”, which will be described later.) The shift amount of the threshold voltage is a difference of the threshold voltage before the applying step and the annealing step. In this case, since the content of the hydrogen molecules and the water molecules contained in the gate insulation film and the gate electrode is made less than 6×10²¹ cm⁻³, the shift amount of the threshold voltage can be effectively reduced, as compared with a condition where the content is equal to or greater than 6×10²¹ cm⁻³.

According to a third aspect of the present disclosure, the content of the hydrogen molecules and the water molecules contained in the gate insulation film and the gate electrode is made equal to or less than 1×10^{21 cm}⁻³ by the pre-annealing step.

According to the characteristic (FIG. 8) that the shift voltage of the threshold voltage depends on the hydrogen content, which is obtained by the inventors' simulation, when the content of the hydrogen molecules and the water molecules is made equal to or less than 1×10²¹ cm⁻³, the shift amount of the threshold voltage can be made substantially zero. That is, the crystal defect generated in the gate insulation film by the applying step can be recovered by the annealing step after the applying.

According to a fourth aspect of the present disclosure, in the manufacturing method of the semiconductor device, the element including the transistor is an insulated gate bipolar transistor (hereinafter, referred to as the IGBT). According to a fifth aspect of the present disclosure, in the manufacturing method of the semiconductor device, the element including the transistor is a double diffusion MOS transistor (hereinafter, referred to as the DMOS).

According to a sixth aspect of the present disclosure, in the manufacturing method of the semiconductor device, the element including the transistor is an element having a barrier metal layer.

As the barrier metal layer used in the element, a metal material having a strong affinity with aluminum or copper used in a wiring is generally used. In the element having the barrier metal layer, hydrogen contained in the barrier metal layer diffuses in the gate insulation film, and the diffused hydrogen becomes hydrogen ion or radical due to the irradiation with the particle ray or the radial ray. Further, this hydrogen ion or radical interacts with the bonding that has been cut in the insulation film, and thus a stable hole trap is generated in the gate insulation film. When the manufacturing method of the semiconductor device described above is employed to the element having the barrier metal layer, the content of the hydrogen molecules or the water molecules contained in the gate insulation film and the gate electrode can be reduced before the applying of the particle ray or the radial ray. By this, among the defects generated by the applying step, the hole trap component stable to the annealing step performed after the applying step can be reduced. That is, the most part of the defect generated by the applying step can be made to a defect unstable to the annealing step. Therefore, the defect in the gate insulation film and the gate electrode can be repaired only by the annealing step, and thus the threshold voltage of the element can be recovered to a level before the applying step.

According to a seventh aspect of the present disclosure, the barrier metal layer is a titanium-based compound.

The titanium-based compound is used for the barrier metal layer, but has a high occluding capacity of hydrogen. When the titanium-based compound is used for the barrier metal layer, the stable hole trap is generated due to the hydrogen occluded. When the manufacturing method of the semiconductor device described above is employed, even in the case where the barrier metal having the high occlusion amount of the hydrogen is used, the defect contained in the gate insulation film and the gate electrode can be repaired only by the annealing step. That is, the threshold voltage of the element can be recovered to the level before the applying step.

According to an eighth aspect of the present disclosure, the semiconductor substrate in which the element has been formed is kept in a vacuum or an inert gas until the applying step finishes after the pre-annealing step.

In this case, in a process until the completion of the applying step, it is possible to keep a state where the number of the hydrogen s or the water molecules in the element (for example, in the gate insulation film or the gate electrode) is reduced. Also in the applying step, diffusion of the hydrogen molecule and/or the water molecule in the element can be reduced. Therefore, the total content of the hydrogen molecules and the water molecules in the element can be reduced, and among the defects generated by the applying step, the generation of the stable hole trap can be reduced. Accordingly, the defect in the gate insulation film and the gate electrode can be repaired only by the annealing step, and thus the threshold voltage of the element can be recovered to a level before the applying step.

According to a ninth aspect of the present disclosure, in the manufacturing method of the semiconductor device, the element forming step includes an interlayer insulation film forming step of forming an interlayer insulation film on the surface of the semiconductor substrate to cover the gate insulation film and the gate electrode. The pre-annealing step is performed after the element forming step. After the pre-annealing step, the semiconductor substrate is kept in a vacuum or an inert gas until the applying step finishes. After the applying step, a barrier metal forming step of forming a barrier metal layer on the interlayer insulation film and a wiring forming step of forming a wiring on the barrier metal layer are performed.

In this manufacturing method of the semiconductor device, the pre-annealing step is performed for reducing the total content of the hydrogen molecules and the water molecules contained in at least the gate insulation film, the gate electrode and the interlayer insulation film, among the components forming the element. The applying step is performed in the vacuum or the inert gas. By this, among the defects generated by the applying step, the component of the hole trap stable to the annealing step performed after the applying step can be reduced. The hydrogen molecules or the water molecules contained in the barrier metal layer and the wiring, which are formed after the applying step, do not cause the stable hole trap unless the particle ray or the radial ray is applied after the barrier metal forming step and the wiring forming step. That is, even if hydrogen occluding metals containing a large amount of hydrogen molecules or water molecules is used as the barrier metal layer, the effect can be reduced. Therefore, the defect in the gate insulation film can be repaired only by the annealing step, and the threshold voltage of the element can be recovered to a level before the applying step.

According to a tenth aspect of the present disclosure, in the manufacturing method of the semiconductor device, the element forming step includes an interlayer insulation film forming step of forming an interlayer insulation film on the surface of the semiconductor substrate to cover the gate insulation film and the gate electrode. After the element forming step, the pre-annealing step is performed. After the pre-annealing step, in a vacuum or an inert gas, a barrier metal forming step of forming a barrier metal layer on the interlayer insulation film and a wiring forming step of forming a wiring on the barrier metal layer are performed. Thereafter, the applying step is performed in a vacuum or an inert gas.

In a case where the applying step is performed after the barrier metal forming step and the wiring forming step, when these three steps are performed in the vacuum or the inert gas, the total content of the hydrogen molecules and the water molecules contained in the gate insulation film, the gate electrode, the interlayer insulation film and the barrier metal layer can be reduced. Further, when the applying of the radial ray or the particle ray is performed in the state where the total content of the hydrogen molecules and the water molecules is small, generation of the stable hole trap is reduced. Therefore, the defect of the gate insulation film is repaired only by the annealing step, and the threshold voltage of the element can be recovered to a level before the applying step.

According to an eleventh aspect of the present disclosure, the semiconductor device includes a semiconductor substrate in which an element including a transistor with a gate electrode and a gate insulation film is formed, and in which a density of stable hole trap in the gate insulation film is equal to or less than 3×10¹¹ cm⁻³.

The hole trap generated in the gate insulation film due to the applying of the particle ray or the radial ray for performing the lifetime control of the element causes a decrease in threshold voltage of the element. In the hole trap, a stable trap level is caused by hydrogen ion or radical generated by decomposition of the hydrogen molecule or the water molecule. The stable hole trap is stable to the annealing performed for the purpose of the recovery of the threshold voltage, and cannot be repaired by an annealing that does not change the lifetime controlled. That is, as the semiconductor described above, the rate of crystal defect that can be repaired only by the annealing performed after the applying of the particle ray or the radial ray can be increased by reducing the density of the stable hole trap in the gate insulation film. That is, the threshold voltage can be recovered only by the annealing. The inventors confirmed, through a computer simulation, a characteristic that the shift amount of the threshold voltage depends on the density of the stable hole trap (see FIG. 9 of “Embodiments for Carrying out Invention”, which will be described later.) According to the computer simulation, the shift amount of the threshold voltage decreases with the reduction of the density of the stable hole trap, and becomes close to zero. In particular, the threshold voltage is easily recovered when the density of the stable hole trap in the gate insulation film is equal to or less than 3×10¹¹ cm⁻³. As described above, the stable hole trap is stable to the annealing performed for the purpose of the recovery of the threshold voltage, and thus the density hardly changes due to the annealing. In other words, the density of the stable hole trap in the gate insulation film being equal to or less than 3×1011 cm⁻³ means that the concentration of the hydrogen molecules or the water molecules in the gate insulation film before the applying the particle ray or the radial ray is equal to or less than a predetermined concentration.

According to a twelfth aspect of the present disclosure, the element including the transistor is an IGBT. According to a thirteenth aspect of the present disclosure, the element including the transistor is a DMOS.

### BRIEF DESCRIPTION OF DRAWINGS

The above and other objects, features and advantages of the present disclosure will become more apparent from the following detailed description made with reference to the accompanying drawings, in which:

FIG. 1 is a cross-sectional view illustrating a schematic structure of a semiconductor device according to a first embodiment;

FIG. 2 is a cross-sectional view for illustrating a diffusion layer forming step and a gate forming step;

FIG. 3 is a cross-sectional view for illustrating a pre-annealing step;

FIG. 4 is a cross-sectional view for illustrating an applying step;

FIG. 5 is a cross-sectional view for illustrating a barrier metal forming step and a wiring forming step;

FIG. 6 is a graph illustrating difference of activation energy of crystal defect between a case where a pre-annealing step is performed and a case where the pre-annealing step is not performed.

FIG. 7 is a graph illustrating characteristics of a collector current Ic depending on a gate voltage Vg;

FIG. 8 is a graph illustrating a characteristic of the shift amount of a threshold voltage Vth depending on a content of hydrogen molecules and water molecules;

FIG. 9 is a graph illustrating a characteristic of the shift amount of the threshold voltage Vth depending on a stable hole trap density;

FIG. 10 is a cross-sectional view for illustrating a barrier metal forming step and a wiring forming step according to a second embodiment; and

FIG. 11 is a cross-sectional view for illustrating an applying step.

### EMBODIMENTS FOR CARRYING OUT INVENTION

Hereinafter, embodiments of the present disclosure will be described with reference to the drawings. It is to be noted that, in the drawings, the same or equivalent parts are designated with the same reference numbers.

### First Embodiment

In the present embodiment, a method for manufacturing an IGBT as an element that includes a transistor having a gate insulation film and a gate electrode will be described.

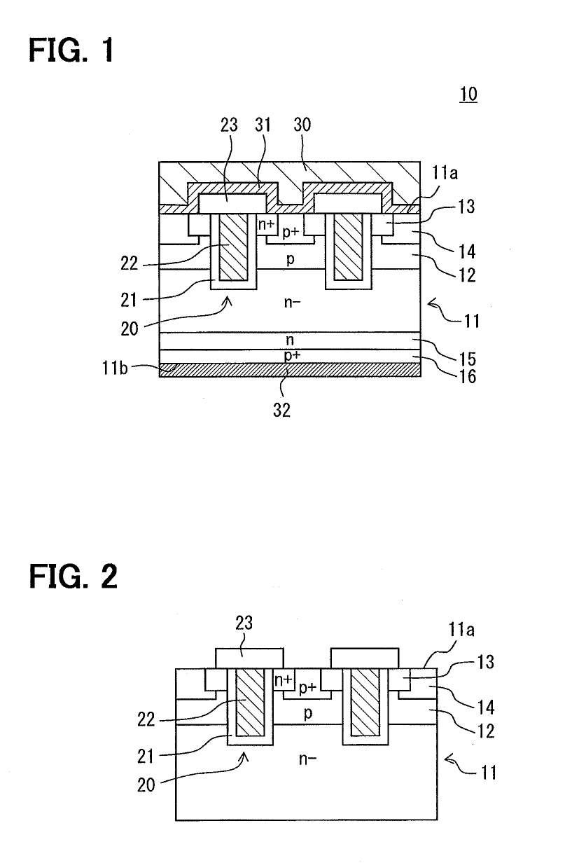

Firstly, a schematic structure of a semiconductor device according to the present embodiment will be described with reference to FIG. 1.

A semiconductor device 10 according to the present embodiment is provided with a vertical-type insulated gate bipolar transistor (IGBT) having a trench gate structure. In the present embodiment, as shown in FIG. 1, a semiconductor substrate 11 uses an n conductivity-type (n) single crystal bulk-silicon substrate that contains silicon as a main component and has an impurity concentration of 1×10¹⁴ cm−3. A p conductivity-type (p) channel layer 12 with an impurity concentration of 2×10¹⁷ cm−3 is formed on a main surface 11a of the semiconductor substrate 11. In the channel layer 12, trenches 20 are selectively formed to penetrate through the channel layer 12 and to extend in a predetermined direction (in a direction perpendicular to a paper plane, in the present embodiment). A plurality of gate electrodes 22 with a trench gate structure is formed in a such a manner that a gate insulation film 21 is formed on a wall surface of the trench 20 and a conductive material (for example, poly-silicon with an impurity concentration of approximately 1×10²⁰ cm⁻³) is filled in the trench 20 through the gate insulation film 21. Each of the gate electrodes 22 extends in a longitudinal direction of the trench 20. The gate electrodes 22 are repeatedly formed at a predetermined pitch in a direction perpendicular to the longitudinal direction. By the gate electrodes 22 disposed in a stripe pattern as described, the channel layer 12 is divided into a plurality of regions that are arranged in the direction perpendicular to an extension direction of the gate electrode 22 and are electrically separated from each other.

In a surface layer of the channel layer 12 adjacent to the main surface 11a, n conductivity-type (n⁺) emitter regions 13 are selectively formed at portions on side surfaces of the gate insulation film 21, as regions having an impurity concentration higher than that of the semiconductor substrate 11. The impurity concentration of the emitter regions 13 is approximately 1×10²⁰ cm⁻³. Further, a p conductivity-type (p+) base contact region 14 is formed in a region between adjacent trenches 20 and between adjacent emitter regions 13. An impurity concentration of the base contact region 14 is approximately 1×10²⁰ cm⁻³.

An interlayer insulation film 23 is selectively formed on the main surface 11a of the semiconductor substrate 11 for electrically separating a wiring 30, which will be described later, and the gate electrode 22. The interlayer insulation film 23 is formed along the extension direction of the gate electrode 22 to cover the gate insulation film 21 and the gate electrode 22.

The wiring 30 is formed on the main surface 11a of the semiconductor substrate 11 in such a manner that the wiring 30 is electrically separated from a non-illustrated gate wiring and covers the interlayer insulation film 23, and the emitter regions 13 and the base contact regions 14, which are exposed from the main surface 11a. A barrier metal layer 31 is formed between the wiring 30 and the interlayer insulation film 23, the emitter regions 13 and the base contact regions 14, so as to improve a connection property of the wiring 30 with the main surface 11a. That is, the wiring 30 is electrically connected to the emitter regions 13 and the base contact regions 14 through the barrier metal layer 31. In the present embodiment, the wiring 30 and the barrier metal layer 31 constitute an emitter electrode of the IGBT. In the present embodiment, as materials for forming the wiring 30 and the barrier metal layer 31, for example, aluminum and titanium nitride can be used, respectively. In the present embodiment, a density of stable hole trap contained in the gate insulation film 21 is made approximately 1×1011 cm⁻³ by the manufacturing method, which will be described later.

On the other hand, in a surface layer of a back surface 11b of the semiconductor substrate 11 opposite to the main surface 11a, an n conductivity-type (n) buffer layer 15 and a p conductivity-type (p⁺) collector layer 16 are formed. The collector layer 16 is exposed on the back surface 11b, and a collector electrode 32 is formed on the entirety of the back surface 11b. In the present embodiment, an impurity concentration of the buffer layer 15 is approximately 3×10¹⁶ cm⁻³, and an impurity concentration of the collector layer 16 is approximately 1×10¹⁸ cm⁻³. Further, as a material of forming the collector electrode 32, for example, aluminum is used.

It is to be noted that the stable hole trap is a lattice defect that is generated as hydrogen ion or radical interacts with Si—Si bond that are cut by irradiation with a radial ray or the like. In regard to the stable hole trap generated in such a mechanism, energy (activation energy) required for repairing thereof is higher than approximately 0.64 eV. (Literature: Submicron device II by Mitsumasa Koyanagi, page 53, Maruzen)

Next, the manufacturing method of the present embodiment will be described with reference to FIGS. 1-5.

First, a diffusion layer forming step and a gate forming step are performed. As shown in FIG. 2, an impurity, such as boron, is doped in the surface layer of the main surface 11a of the semiconductor substrate 11 to form the p-type channel layer 12. Then, the trenches 20 are formed from a surface of the semiconductor substrate 11 adjacent to the main surface 11a to penetrate through the channel layer 12 and to extend in the predetermined direction. Further, the gate insulation film 21 is formed on the inner wall of the trenches 20, for example, with silicon oxide (SiO₂). Thereafter, the gate electrode 22 is formed inside of the trench 20 by filling a doped poly silicon, for example. Further, the base contact region 14 is formed by doping boron or the like in the region between the adjacent trenches 20. The plurality of n⁺-type emitter regions 13 is formed by doping an impurity such as phosphorus, so that the emitter regions 13 abut on the side surfaces of the trenches 20 in the direction perpendicular to the extension direction of the trenches 20 and extend in the extension direction of the trenches 20 on the surface layer of the channel layer 12. The order of forming the trenches 20 and the emitter regions 13 is not limited to the order described above. That is, the trenches 20 and the emitter regions 13 may be formed as follows: the emitter region 13 is formed in a region between the adjacent base contact regions 14 to expose from the main surface 11a and to be surrounded by the channel layer 12; the trench 20 is then formed to penetrate through the emitter region 13 and the channel layer 12; and the gate insulation film 21 and the gate electrode 22 are thereafter formed.

Next, an interlayer insulation film forming step is performed. As shown in FIG. 2, the interlayer insulation film 23 is formed to cover the gate insulation film 21 and the gate electrode 22. The interlayer insulation film 23 is formed along the extension direction of the trenches 20.

In the present embodiment, the steps described hereinabove correspond to an element forming step.

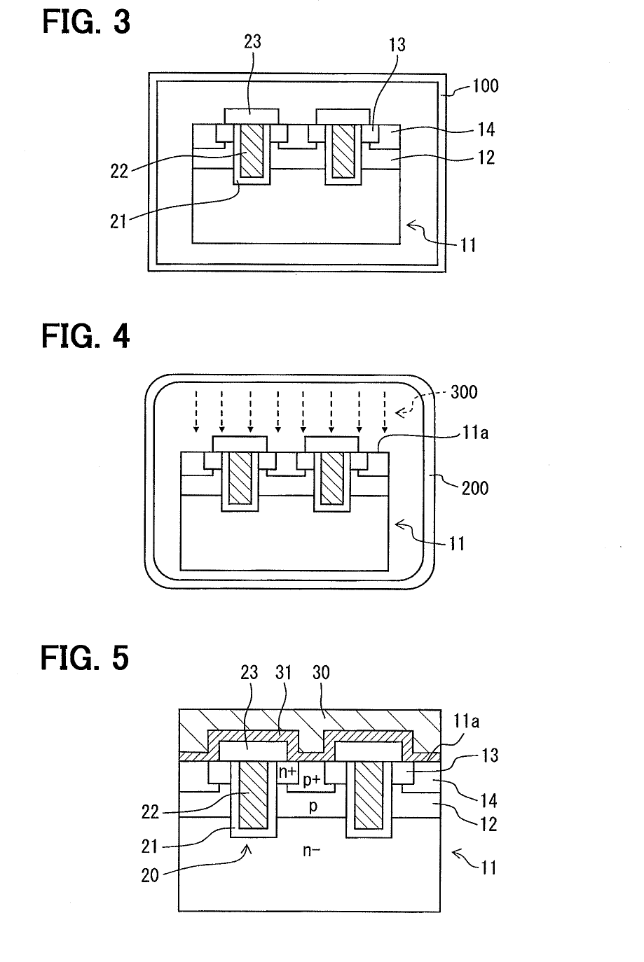

Next, a pre-annealing step is performed for extracting hydrogen or water from the gate insulation film 21 and the gate electrode 22. As shown in FIG. 3, the semiconductor substrate 11, which has undergone the element forming step, is placed in a heating furnace 100. The semiconductor substrate 11 is heated for approximately one hour at a temperature from 380° C. to 550° C. (in the present embodiment, for example, approximately 380° C.) under a nitrogen atmosphere. It is to be noted that the pre-annealing step may be performed by a lamp-heating method.

Next, an applying step is performed for the lifetime control of the element. As shown in FIG. 4, the semiconductor substrate 11 immediately after the pre-annealing step is placed in a vacuum chamber 200. An electron ray 100 is applied toward the main surface 11a of the semiconductor substrate 11 while keeping the vacuum chamber 200 at the degree of vacuum from approximately 1×10⁻⁶ Pa to 1 Pa (in the present embodiment, for example, approximately 1×10⁻⁵ Pa). An absorbed dose of the electron ray 300 is preferably from 40 kGy to 100 kGy, and may be 40 kGy, for example, in the present embodiment.

Next, a barrier metal forming step is performed. As shown in FIG. 5, the barrier metal layer 31 is formed to cover the emitter regions 13 and the base contact regions 14, which are exposed from the main surface 11a, while being electrically separated from the non-illustrated gate wiring. As the material of forming the barrier metal layer 31, titanium nitride may be used, as described above. The barrier metal layer 31 may be accumulated by a spattering technique.

Next, a wiring forming step is performed. As shown in FIG. 5, the wiring 30 is formed to cover the barrier metal layer 31. As the material of forming the wiring 30, aluminum may be used, as described above, The wiring 30 may be accumulated by a spattering technique.

Next, a step of forming the buffer layer 15, the collector layer 16 and the collector electrode 32 on the back surface 11b of the semiconductor substrate 11 opposite to the main surface 11a, as shown in FIG. 1, is performed. First, the semiconductor substrate 11 is made thin by grinding from the back surface 11b. Then, the buffer layer 15 is formed by doping phosphorous or the like from the rear surface 11b. Thereafter, the collector layer 16 is formed by doping boron or the like from the back surface 11b. The collector layer 16 exposes from the back surface 11b. Further, the collector electrode 32 is formed by accumulating aluminum or the like on the entirety of the rear surface 11b by the spattering technique.

Although not illustrated, an annealing step is lastly performed for repairing the crystal defect generated in the gate insulation film 21 and the gate electrode 22 by the applying step. The annealing step is performed by placing the semiconductor substrate 11 in the heating furnace 100, similarly to the pre-annealing step and by heating the semiconductor substrate 11 for approximately one hour at a temperature from 300° C. to 400° C. (in the present embodiment, for example, approximately 330° C.) under a hydrogen atmosphere in the heating furnace 100.

By the above-described steps, the semiconductor device 10 of he present embodiment, as shown in FIG. 1, is produced.

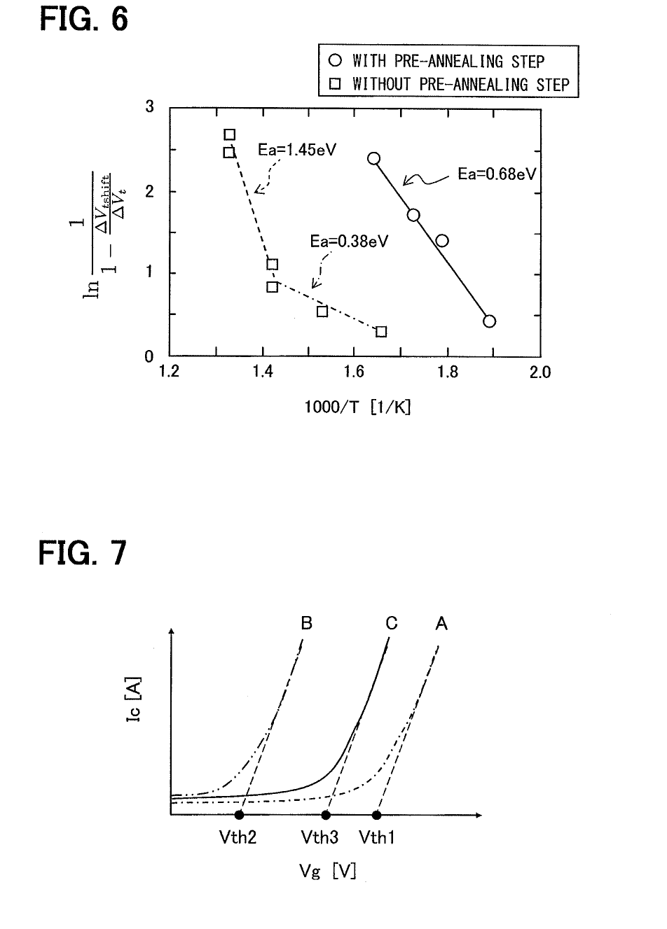

Next, effects of the semiconductor device 10 and the manufacturing methods of the semiconductor device 10 according to the present embodiment will be described with reference to FIGS. 6-9.

The characteristic portion of the manufacturing method of the semiconductor device 10 according to the present embodiment is that the pre-annealing step is performed before the applying step in which the electron ray is applied to the semiconductor substrate 11. By performing the pre-annealing step, the rate of the thermally stable hole trap as the crystal defect generated in the gate insulation film 21 due to the applying step can be reduced.

The inventors examined activation energy of the crystal defect existing in the gate insulation film 21 of a case where the pre-annealing step is performed and a case where the pre-annealing step is not performed, and obtained the results shown in FIG. 6. FIG. 6 is a single logarithmic chart in which a horizontal axis represents a reciprocal number of the annealing temperature of the annealing step, and a vertical axis represents the rate of change (ΔVt) of the threshold voltage of the case where the annealing step is not performed, relative to the rate of change (ΔVt−ΔVtshift) from the initial threshold voltage to the threshold voltage after the annealing step. In the graph of FIG. 6, the gradient of a line corresponds to the activation energy. According to the graph, it is appreciated that the crystal defect with 1.45 eV activation energy, which exists when the pre-annealing step is not performed, hardly exists in the case where the pre-annealing step is performed. The crystal defect with the 0.68 eV activation energy (corresponding to the above-described defect with 0.64 eV activation energy), which exists in the case where the pre-annealing step is performed, can be reduced in number at the lower temperature, as compared with the crystal defect that exists in the case where the pre-annealing is not performed. That is, the crystal defect can be easily recovered by the annealing step.

As described above, in the case where the applying step is performed after the pre-annealing step, and the annealing step is then performed, the almost of the crystal defect generated in the gate insulation film 21 can be recovered. Thus, the threshold voltage can be recovered to the level substantially equal to the level before the applying step. Therefore, in the semiconductor device 10 manufactured by the method described above, the density of the thermally stable defect in the gate insulation film 21 is lower than that of the case without performing the pre-annealing step.

Hereinafter, a detailed mechanism will be described.

The change of the threshold voltage Vth of the case where the pre-annealing step is not performed before the applying step will be described with reference to FIG. 7. FIG. 7 indicates the change (I-V characteristic) of a collector current Ic flowing in the collector electrode 32, with respect to a gate voltage Vg applied to the gate electrode 22. A single-dashed chain line (A in FIG. 7) is the I-V characteristic of an IGBT that is manufactured without performing the pre-annealing step and the applying step. That is, the threshold voltage of this characteristic curve A corresponds to a threshold voltage Vth1 before the applying step. A double-dashed chain line (B in FIG. 7) is the I-V characteristic of an IGBT that is manufactured with the applying step without the pre-annealing step. That is, the threshold voltage of the characteristic curve B corresponds to a threshold voltage Vth2 after the applying step. A solid line (C in FIG. 7) is the I-V characteristic of an IGBT that is manufactured by performing the applying step without the pre-annealing step, and performing the annealing step after the applying step. That is, the threshold voltage of the characteristic curve C corresponds to a threshold voltage Vth3 of the case where the annealing step is performed after the applying step. Therefore, the shift amount of the threshold voltage Vth described above corresponds to Vth3−Vth1.

The crystal defect is generated in the channel layer 12 by performing the applying step. Since the trap level with the gate insulation film 21 with the channel layer 12 can be changed (the level of trapping the carriers can be increased), the lifetime of the carriers can be controlled. On the other hand, the crystal defect is generated also in the gate insulation film 21. Therefore, the threshold voltage Vth reduces (changes from Vth1 to Vth2), as shown in FIG. 7.

In the case where the pre-annealing step is not performed before the applying step, the element, in particular, the gate insulation film 21 and the gate electrode 22 are in the state of containing a large amount of the hydrogen molecules and the water molecules during the applying step. Therefore, these molecules are decomposed by the electron ray, and thus the hydrogen ion or hydrogen radical is generated. This hydrogen ion or radical interacts with the Si—Si bond that are cut and exist in the gate insulation film 21, resulting in the stable hole trap. This stable hole trap is thermally stable, and cannot be repaired by the temperature approximately of the annealing step (300° C. to 400° C.). Therefore, although the threshold voltage Vth can be recovered to some level (changed from Vth2 to Vth3) due to the thermally unstable crystal defect being repaired in the annealing step, the threshold voltage Vth cannot be recovered to the level before the applying step, that is, to Vth1.

As described above, the main cause of the shift of the threshold voltage Vth (Vth3−Vth1=/0) is the hydrogen molecules and the water molecules contained in the gate insulation film 21 and the gate electrode 22. When the concentrations of the hydrogen molecules and the water molecules are reduced by performing the pre-annealing step before the applying step of applying the electron ray to the semiconductor substrate 11, the shift amount of the threshold voltage Vth can be reduced.

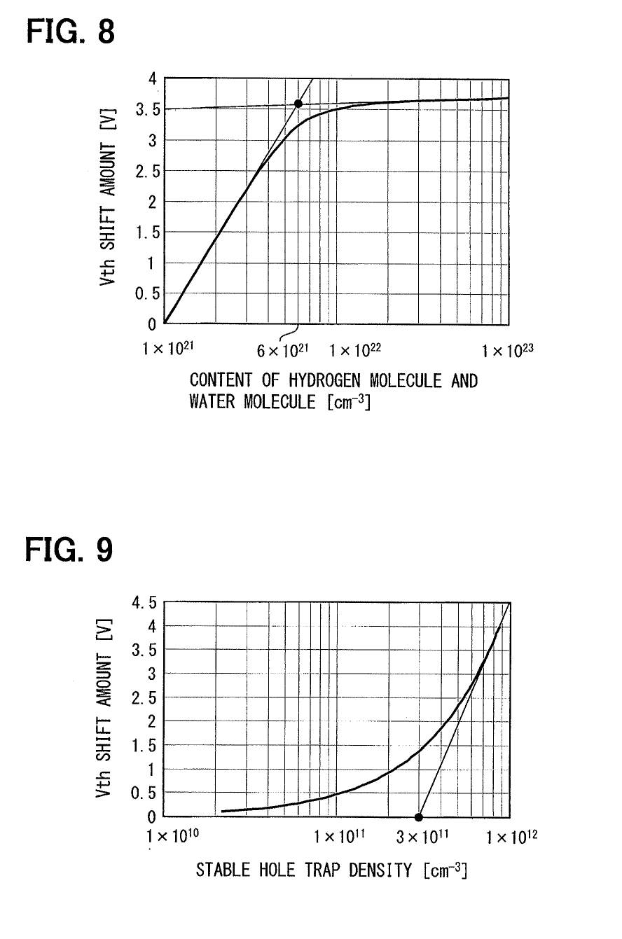

The inventors confirmed, through a computer simulation, the shift amount of the threshold voltage Vth with respect to the content of the hydrogen molecules and water molecules contained in the gate insulation film 21 and the gate electrode 22. FIG. 8 illustrates the result of the computer simulation indicating that the shift amount of the threshold voltage reduces with the decrease in content of the hydrogen molecules and the water molecules. The simulation result indicates that the shift amount of the threshold voltage can be effectively reduced when the content is made lower than 6×10²¹ cm³. Moreover, the simulation result indicates that the shift amount of the threshold voltage can be made substantially zero when the content is made equal to or less than 1×10²¹ cm⁻³.

The inventors also confirmed, through a computer simulation, the shift amount of the threshold voltage Vth with respect to the density of the stable hole trap existing in the gate insulation film 21 of the IGBT manufactured. FIG. 9 illustrates the result of the computer simulation indicating that the shift amount of the threshold voltage reduces with the decrease of the density of the stable hole trap. The simulation result indicates that the shift amount of the threshold voltage is effectively reduced when the density of the stable hole trap is made equal to or less than 3×10¹¹ cm⁻³.

As described above, in the manufacturing method of the semiconductor device 10 according to the present embodiment, the threshold voltage before the applying can be ensured without setting the concentration of the impurity doped in the semiconductor substrate 11 to a higher level. In the semiconductor device 10 manufactured by this method, variation in threshold voltage due to the increase in the dose amount of the impurity is reduced.

### Second Embodiment

In the first embodiment, the example in which the applying step is performed immediately after the pre-annealing step is described. In the present embodiment, on the other hand, an example in which the applying step is performed after the barrier metal forming step and the wiring forming step, after the pre-annealing step.

Firstly, a manufacturing method of a semiconductor device 10 according to the present embodiment will be described with reference to FIGS. 1-3, 10 and 11.

First, as shown in FIG. 2, the diffusion layer forming step, the gate forming step, and the interlayer insulation film forming step are performed. These steps are the same as those of the first embodiment, and thus detailed descriptions thereof will be omitted. In the present embodiment, these steps correspond to the element forming step.

Next, as shown in FIG. 3, the pre-annealing step is performed. The pre-annealing step is also the same as that of the first embodiment, and thus a detailed description thereof will be omitted.

Next, the barrier metal forming step is performed. In the present embodiment, as shown in FIG. 10, the semiconductor substrate 11, which is immediately after the pre-annealing step, is placed in a vacuum chamber 200. The barrier metal layer 31 is formed by a spattering technique while keeping the inside of the vacuum chamber 200 at a vacuum degree of approximately 1×10⁻⁶ Pa to 1 Pa (in the present embodiment, for example, approximately 1×10 Pa), to cover the interlayer insulation film 23 and the emitter regions 13 and the base contact regions 14, which are exposed from the main surface 11a. Also in the present embodiment, as a material of forming the barrier metal layer, titanium nitride may be used.

Next, the wire forming step is performed. In the present embodiment, as shown in FIG. 10, the wiring 30 is formed in the state where the semiconductor substrate 11 is kept in the vacuum chamber 200 after the barrier metal forming step. As a material of forming the wiring 30, aluminum may be used, similar to the first embodiment. The aluminum can be accumulated by the spattering technique.

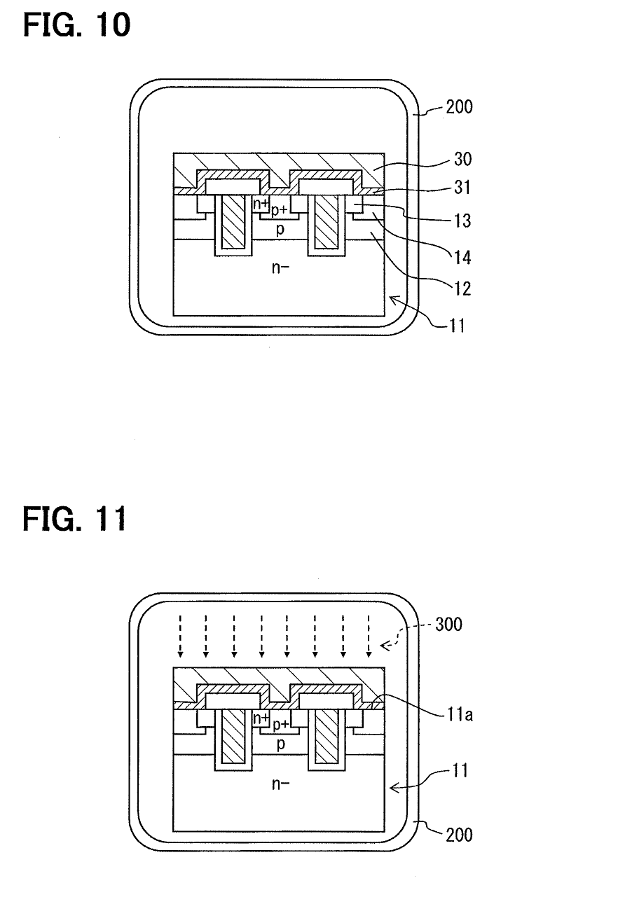

Next, the applying step is performed. As shown in FIG. 11, subsequent to the barrier metal forming step and the wiring forming step, an electron ray 300 is applied toward the main surface 11a of the semiconductor substrate 11 inside of the vacuum chamber 200. The absorbed dose of the electron ray 300 is preferably from 40 kGy to 100 kGy, and, for example, 40 kGy in the present embodiment.

Thereafter, the steps of forming the buffer layer 15, the collector layer 16 and the collector electrode 32 on the back surface 11b of the semiconductor substrate 11 opposite to the main surface 11 a are performed, and then the annealing step is performed. These steps are also the same as those of the first embodiment, and thus detailed description thereof will be omitted.

By the above-described steps, the semiconductor device 10 as shown in FIG. 1 can be manufactured.

Next, effects of the semiconductor device 10 and the manufacturing method of the semiconductor device 10 of the present embodiment will be described.

Differently from the first embodiment in which the applying step is performed immediately after the pre-annealing step, the barrier metal forming step and the wiring forming step can be performed after the pre-annealing step and then the applying step can be performed after the barrier metal forming step and the wiring forming step, as the manufacturing method of the semiconductor device 10 of the present embodiment. In this way, when another step is performed between the pre-annealing step and the applying step, it is preferable to perform the step in the vacuum or the inert gas, as the present embodiment.

In the barrier metal forming step, when the forming of the layer of the titanium nitride by the spattering technique is performed in the vacuum or the inert gas, the barrier metal layer 31 containing a small amount of the hydrogen molecules or the water molecules can be formed. Also in the wiring forming step, when the forming of the aluminum wiring by the spattering technique is performed in the vacuum or the inert gas, the wiring 30 containing a small amount of the hydrogen molecules or the water molecules can be formed. Therefore, the number of the hydrogen molecules or the water molecules diffusing to the gate insulation film 21 and the gate electrode 22 from the barrier metal layer 31 and the wiring 30 can be reduced. In the applying step, therefore, it is less likely that the hydrogen molecules or the water molecules in the gate insulation film 21 will be decomposed by the electron ray and will become ion or radical. Accordingly, the generation of the thermally stable hole trap can be reduced. Further, the threshold voltage Vth, which has been reduced by the applying step, can be almost recovered by performing the annealing step.

### Third Embodiment

In each of the embodiments described above, the example in which the element including the transistor having the gate insulation film and the gate electrode is the vertical IGBT with the trench gate structure is described. However, the element including the transistor is not limited to the IGBT. For example, the element including the transistor may be a vertical-type double diffusion MOS with a trench gate structure (hereinafter, referred to as DMOS).

Although not illustrated, a semiconductor device 10 of the present embodiment is configured so that the collector layer 16 is not formed and the buffer layer 15 is exposed on the back surface 11b of the semiconductor substrate 11, relative to the structure of the IGBT (FIG. 1) indicated in the first embodiment or the second embodiment. In such a structure, the wiring 30 of the first embodiment or the second embodiment functions as a wiring on a source side (source electrode), and the collector electrode 32 functions as an electrode on a drain side (drain electrode).

In regard to the manufacturing method, the method indicated in the first embodiment or the second embodiment can be used. The collector layer 16 may not be formed, and the buffer layer 15 may be formed to expose on the back surface 11b of the semiconductor substrate 11.

Effects of the semiconductor device 10 of the present embodiment and the manufacturing method thereof are the same as those of each embodiment described above, and thus detailed description thereof will be omitted.

### Other Embodiments

Hereinabove, embodiments of the present disclosure are described. However, the present disclosure is not limited to the embodiments described hereinabove, but may be implemented by modifying the embodiments in various ways without departing from the gist of the present disclosure.

In the first embodiment, it is described the example in which the annealing step is performed after the barrier metal forming step and the wiring forming step, after the applying step. However, the annealing step may be performed at any timing as long as it is performed after the applying step.

In each of the embodiments described hereinabove, it is described the example in which the semiconductor substrate is kept in the vacuum or in the inert gas until the applying step finishes, after the pre-annealing step. However, it is not always necessary to keep the semiconductor substrate in the vacuum or in the inert gas. It is preferable to perform a process until the applying step finishes after the pre-annealing step under an environment which contains less hydrogen molecules or water molecules.

In each of the embodiments described hereinabove, the example in which the semiconductor substrate is kept in the vacuum until the applying step finishes, after the pre-annealing step. However, the example is not limited to be performed in the vacuum, but may be performed in an inert gas such as nitrogen or argon.

In each of the embodiments described above, it is described the example in which the material of forming the barrier metal layer is titanium nitride. However, the material of the barrier metal layer is not limited to the titanium nitride, but may be titanium tungsten (TiW) or tantalum nitride (TaN).

In each of the embodiments described hereinabove, the structure of having the barrier metal layer is described as an example. However, the structure is not limited to the example described hereinabove, but the present disclosure may be employed to a structure without having the barrier metal layer.

In each of the embodiments described above, as the example of the particle ray or the radial ray applied in the applying step, the electron ray is applied. However, the ray applied in the applying step is not limited to the electron ray. For example, a particle ray, such as a helium ray or a neutron ray, or a radial ray, such as a gamma ray or an X-ray, may be used.

In each of the embodiments described above, it is described the example in which the element including the transistor with the gate insulation film and the gate electrode has the trench gate structure. This element is not limited to the trench gate type. For example, the element may be an IGBT or a DMOS having a planer gate structure.

In each of the embodiments described hereinabove, the element including the transistor with the gate insulation film and the gate electrode is the vertical-type element. However, this element is not limited to the vertical-type element. For example, the element may be a lateral-type IGBT or DMOS.

Further, the element is not limited to the IGBT or the DMOS exemplified in each of the embodiments described hereinabove. That is, the present disclosure may be employed to an element having a structure in which an electric current flowing between electrodes of a semiconductor substrate is controlled by a voltage applied to a gate electrode having a gate insulation film, which is so-called a CMOS structure.

Furthermore, the present disclosure ay not be limited to an example in which an IGBT or a DMOS is solely formed in a semiconductor substrate. In particular, the present disclosure may be suitable to a structure in which an IGBT and a diode (free wheeling diode: FWD) are formed in the same semiconductor substrate, which is so-called RC-IGBT. In the RC-IGBT, a He ray is generally applied to a surface of the semiconductor substrate on which the gate insulation film of the IGBT is formed, in order to reduce DC loss of the FWD. Therefore, a crystal defect is easily generated in the gate insulation film of the IGBT. As such, when the present disclosure is employed to the RC-IGBT, the crystal defect of the gate insulation film can be effectively recovered. That is, the shift amount of the threshold voltage Vth of the IGBT can be reduced, and the DC loss of the FWD can be reduced.

1. A manufacturing method of a semiconductor device, comprising:
forming an element including a transistor having a gate insulation film and a gate electrode adjacent to a surface of a semiconductor substrate;
applying at least one of a particle ray and a radial ray to the semiconductor substrate from a side adjacent to the surface, after the the forming of the element;
annealing the semiconductor substrate by heating the semiconductor substrate for recovering a crystal defect contained in the gate insulation film and the gate electrode, after the applying; and
pre-annealing the semiconductor substrate by heating the semiconductor substrate for reducing a content of a hydrogen molecule and a water molecule contained in the gate insulation film and the gate electrode, before the applying.

2. The manufacturing method of the semiconductor device according to claim 1, wherein the content is made less than 6×10²¹ cm⁻³ by the pre-annealing.

3. The manufacturing method of the semiconductor device according to claim 2, wherein the content is made equal to or less than 1×10²¹ cm⁻³ by the pre-annealing.

4. The manufacturing method of the semiconductor device according to claim 1, wherein the element is an insulated gate bipolar transistor.

5. The manufacturing method of the semiconductor device according to claim 1, wherein the element is a double diffusion MOS transistor.

6. The manufacturing method of the semiconductor device according to claim 1, wherein the element has a barrier metal layer.

7. The manufacturing method of the semiconductor device according to claim 6, wherein the barrier metal layer is a titanium compound.

8. The manufacturing method of the semiconductor device according to claim 1, wherein the semiconductor substrate in which the element has been formed is kept in a vacuum or an inert gas after the pre-annealing and until the applying finishes.

9. The manufacturing method of the semiconductor device according to claim 7, wherein
the forming of the element includes forming an interlayer insulation film on the surface of the semiconductor substrate to cover the gate insulation film and the gate electrode,
the pre-annealing is performed after the forming of the element, and
the semiconductor substrate is kept in a vacuum or an inert gas after the pre-annealing and until the applying finishes, the manufacturing method further comprising
forming the barrier metal layer on the interlayer insulation film and forming a wiring on the barrier metal layer, after the applying.

10. The manufacturing method of the semiconductor device according to claim 7, wherein
the forming of the element includes forming an interlayer insulation film on the surface of the semiconductor substrate to cover the gate insulation film and the gate electrode, and
the pre-annealing is performed after the forming of the element, the manufacturing method further comprising
forming the barrier metal layer on the interlayer insulation film and forming a wiring on the barrier metal layer, in a vacuum or an inert gas, after the pre-annealing, wherein
the applying is performed in a vacuum or an inert gas, after the forming of the wiring.

11. A semiconductor device comprising:
a semiconductor substrate having an element, the element including a transistor having a gate electrode and a gate insulation film, wherein
a density of a stable hole trap in the gate insulation film is equal to or less than 3×10¹¹ cm⁻³.

12. The semiconductor device according to claim 11, wherein the element is an insulated gate bipolar transistor.

13. The semiconductor device according to claim 11, characterized wherein the element is a double diffusion MOS transistor.
